(19) United States
(12) Patent Application Publication
(10) Pub. No.: US 2009/0185356 A1
(43) Pub. Date: Jul. 23, 2009

(54) BOARD ASSEMBLY

(75) Inventors: Ting-Hui Liao, Taipei (TW); Chia-Huang Chan, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: PEGATRON CORPORATION, TAIPEI CITY (TW)

(21) Appl. No.: 12/332,354

(22) Filed: Dec. 11, 2008

(30) Foreign Application Priority Data
Jan. 21, 2008 (TW) 97102189

(51) Int. Cl. H05K 5/00

(52) U.S. Cl. 361/759

(57) ABSTRACT

A board assembly adapted to cooperate with one of a first expansion card and a second expansion card having different sizes. The board assembly includes a board, a connector, a first securing unit, a second securing unit and a plurality of locking elements. The connector, the first securing unit and the second securing unit are disposed at the board. The first securing unit is closer to the connector than the second securing unit. One end of the expansion card is inserted into the connector, and another end of the expansion card is locked at the first securing unit or the second securing unit by the locking element.

### CROSS-REFERENCE TO RELATED APPLICATION

This application claims the priority benefit of Taiwan application serial no. 97102189, filed on Jan. 21, 2008. The entirety of the above-mentioned patent application is hereby incorporated by reference herein and made a part of this specification.

### BACKGROUND OF THE INVENTION

1. Field of the Invention

The invention relates to a board assembly and, more particularly, to a board assembly assembled in a computer main unit.

2. Description of the Related Art

Generally speaking, a computer has boards for providing basic functions and expansion cards having different functions may be selectively added to improve the performance of the computer. For example, if a wireless network card or a television card is not built in the computer, an expansion card for performing the function such as wirelessly accessing the Internet or watching TV may be selectively added to the computer.

From the above, the expansion card is, for example, a mini card or other kind of card. A board has connectors corresponding to expansion cards and securing units. The expansion card is secured between the connector and the securing unit. In detail, the expansion card is inserted to the connector firmly with the assistance of the securing unit to be electrically connected to the board. General expansion cards have two different sizes, which are full size and half size, manufacturers must manufacture securing assemblies of two different sizes for different expansion cards.

### BRIEF SUMMARY OF THE INVENTION

The invention provides a board assembly which is suitable to fix a half-size expansion card or a full-size expansion card.

The invention provides a board assembly suitable to cooperate with one of a first expansion card and a second expansion card having different sizes. The board assembly includes a board, a connector, a first securing unit, a second securing unit and a locking element. The connector, the first securing unit and the second securing unit are disposed at the board. The first securing unit is closer to the connector than the second securing unit. When the board assembly cooperates with the first expansion card, one end of the first expansion card is inserted into the connector, and another end of the first expansion card is locked at the first securing unit by the locking element. When the board assembly cooperates with the second expansion card, one end of the second expansion card is inserted into the connector, and another end of the second first expansion card is locked at the second securing unit by the locking element.

In one embodiment of the invention, the first securing unit or the second securing unit includes a supporting unit for supporting the expansion card locked at the first securing unit by the locking element. In one embodiment of the invention, each of the first securing unit and the second securing unit includes two studs.

In one embodiment of the invention, the supporting unit and the stubs are provided at opposite surfaces of the board.

In one embodiment of the invention, the board has holes for the supporting unit to pass through.

In one embodiment of the invention, the locking elements are screws.

In one embodiment of the invention, the board is a wireless network card or a television card.

In one embodiment of the invention, the first expansion card and the second expansion card may be a half-size expansion card and a full-size expansion card, respectively. Therefore, both of the half-size expansion card and a full-size expansion card are able to be disposed on the board assembly of the invention.

Compared with the conventional technology, the first securing unit and the second securing unit are disposed on the board of the invention, the half-size expansion card or the full-size expansion card may be secured in the board assembly of the invention correspondingly to the securing position thereof. In other words, the board assembly of the invention has a characteristic of cooperating with a half-size expansion card or a full-size expansion card, and it has preferred assembly compatibility.

These and other features, aspects, and advantages of the present invention will become better understood with regard to the following description, appended claims, and accompanying drawings.

### BRIEF DESCRIPTION OF THE DRAWINGS

FIG. 1A is a three-dimensional schematic diagram showing a board assembly on which an expansion card is secured according to one embodiment of the invention.

FIG. 1B is an exploded diagram showing the board assembly shown in FIG. 1A.

FIG. 2 is a three-dimensional schematic diagram showing the board assembly shown in FIG. 1A and on which an expansion card with another size is secured.

### DETAILED DESCRIPTION OF THE EMBODIMENTS

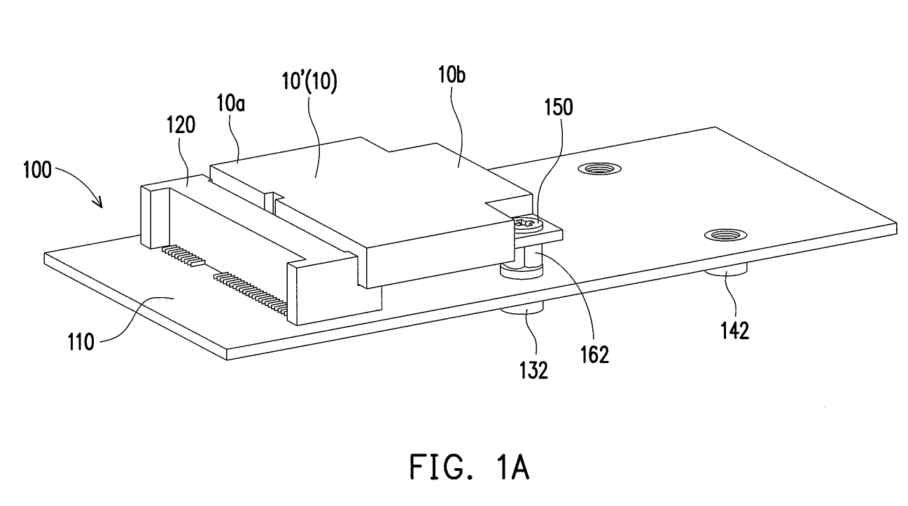

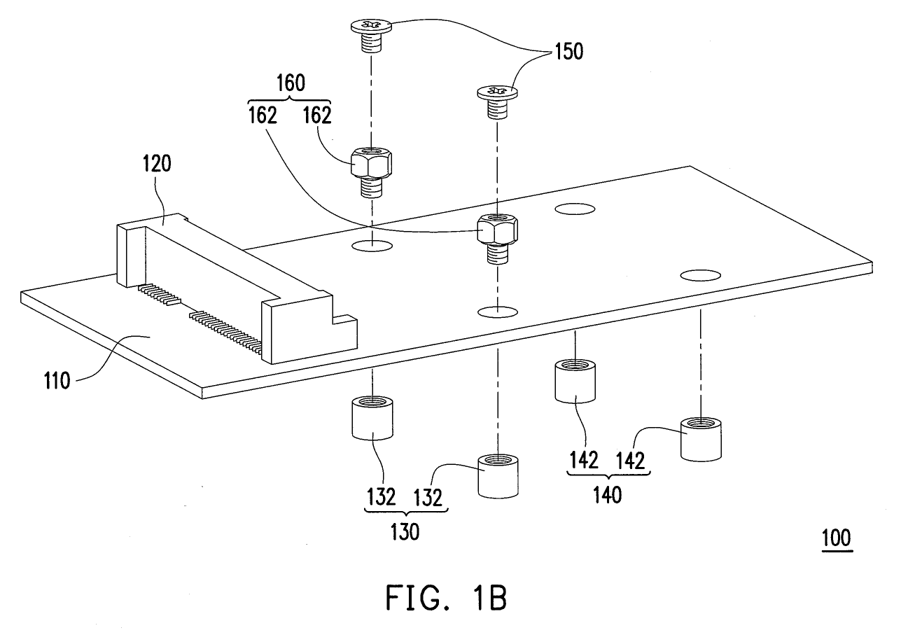

FIG. 1A is a three-dimensional schematic diagram showing a board assembly on which an expansion card is secured according to one embodiment of the invention. FIG. 1B is an exploded diagram showing the board assembly in FIG. 1A. As shown in FIG. 1A and FIG. 1B, the board assembly 100 of the embodiment is suitable to cooperate with an expansion card 10 having a first end 10a and a second end 10b. In addition, the board assembly 100 of the embodiment includes a board 110, a connector 120, a first securing unit 130, a second securing unit 140 and a plurality of locking elements 150.

From the above, the board 110 of the embodiment is, for example, the expansion card having different sizes may be a wireless network card or a television card. The connector 120, the first securing unit 130 and the second securing unit 140 are disposed at the board 110. The first securing unit 130 comprises two studs 132, and the second securing unit 140 comprises two studs 142. The first securing unit 130 is closer to the connector 120 than the second securing unit 140.

In detail, the distance between the connector 120 and the first securing unit 130 is equal to the length of the half-size expansion card, and the distance between the connector 120 and the second securing unit 140 is equal to the length of the full-size expansion card. The expansion card 10 in FIG. 1A is a half-size expansion card 10′, and the first end 10a is inserted to the connector 120. The half-size expansion card 10′ is electrically connected to the board 110 by the connector 120 to perform the function of the expansion card. Thus, the performance of the board assembly 100 is improved.

In addition, the first securing unit 130 includes a supporting unit 160 for supporting the first expansion card. The locking elements 150 such as screws are suitable to pass through the second end 10b of the half-size expansion card 10′ and are locked at a supporting unit 160. Thus, the half-size expansion card 10′ is secured to the board 110. In detail, the supporting unit 160 and the stubs 132 are provided at opposite surfaces of the board and the board 110 has holes for the supporting unit 160 to pass through. The supporting unit 160 supports the second end 10b of the half-size expansion card 10′ to allow the half-size expansion card 10′ whose one end is inserted to the connector 120 to maintain a horizontal state. Thus, the half-size expansion card 10′ and the connector 120 have a good electrical connecting relationship (If the half-size expansion card 10′ is obliquely disposed, it is easily separated from the connector 120 and cannot be electrically connected to the board 110).

In detail, the supporting unit 160 of the embodiment includes two supporting posts 162 locked to the corresponding studs 132 to support the second end 10b of the half-size expansion card 10′. Thus, the half-size expansion card 10′ maintains a horizontal state. The locking elements 150 pass through the second end 10b of the half-size expansion card 10′, and they are locked to the corresponding supporting post 162. Thus, the half-size expansion card 10′ is secured at the board assembly 100 by the locking elements 150 and the first securing unit 130.

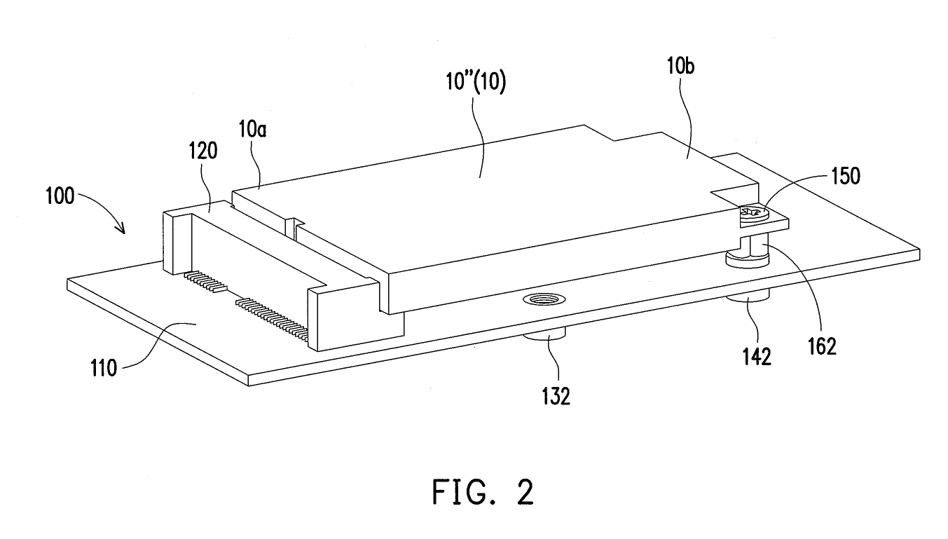

As shown in FIG. 1B and FIG. 2, when the expansion card is a full-size expansion card 10″ (FIG. 2 is a three-dimensional schematic diagram showing the board assembly shown in FIG. 1A and on which an expansion card with another size is fixed). The first end 10a is also inserted to the connector 120, and the locking elements 150 such as screws are also suitable to pass through the second end 10b of the full-size expansion card. Since the length of the full-size expansion card 10″ is equal to the distance between the connector 120 and the second securing unit 140. In the embodiment, the second securing unit 140 includes the supporting unit 160 for supporting the full-size expansion card 10″, and the locking elements 150 are used to lock the full-size expansion card to the supporting unit 160.

In detail, in FIG. 2, the second securing unit 140 includes two supporting posts 162 are locked to the two studs 142. The two supporting posts 162 are locked to the two studs 142 to support the second end 10b of the full-size expansion card 10″. The locking elements 150 passing through the second end 10b of the full-size expansion card 10″ are locked to the supporting posts 162. In this way, the full-size expansion card 10″ also maintains a horizontal state by the assistance of the supporting unit 160. The full-size expansion card 10″ is secured to the board assembly 100 by the locking elements 150 and the second securing unit 140.

When the expansion card 10 is firmly inserted to the connector 120, the locking elements 150 passing through the second end 10b of the expansion card 10 also may be directly locked to the first securing unit 130 or the second securing unit 140, which is not limited.

To sum up, in the board assembly of the invention, the board has a connector to which the first end of an expansion card is inserted, a first securing unit suitable to secure a half-size expansion card to the board and a second securing unit suitable to secure a full-size expansion card to the board. The locking elements pass through the second end of the expansion card, and they are locked to one of the first securing unit and the second securing unit. Thus, the expansion card is efficiently and fixedly connected to the board assembly.

Although the present invention has been described in considerable detail with reference to certain preferred embodiments thereof, the disclosure is not for limiting the scope of the invention. Persons having ordinary skill in the art may make various modifications and changes without departing from the scope and spirit of the invention. Therefore, the scope of the appended claims should not be limited to the description of the preferred embodiments described above.

What is claimed is:

1. A board assembly adapted to cooperate with one of a first expansion card and a second expansion card having different sizes, the board assembly comprising:
a board;
a connector disposed at the board;
a first securing unit disposed at the board;
a second securing unit disposed at the board, wherein the first securing unit is closer to the connector than the second securing unit; and
a locking element,
wherein when the board assembly cooperates with the first expansion card, one end of the first expansion card is inserted into the connector, and another end of the first expansion card is locked at the first securing unit by the locking element, and
wherein when the board assembly cooperates with the second expansion card, one end of the second expansion card is inserted into the connector, and another end of the second first expansion card is locked at the second securing unit by the locking element.

2. The board assembly according to claim 1, wherein the first securing unit further comprising a supporting unit for supporting the first expansion card, and the locking element is locked at the supporting unit.

3. The board assembly according to claim 2, wherein each of the first securing unit and the second securing unit comprises two studs.

4. The board assembly according to claim 3, wherein the supporting unit and the stubs are provided at opposite surfaces of the board.

5. The board assembly according to claim 2, wherein the board has holes for the supporting unit to pass through.

6. The board assembly according to claim 1, wherein the second securing unit further comprises a supporting unit for supporting the second expansion card, and the locking element is locked at the supporting unit.

7. The board assembly according to claim 6, wherein each of the first securing unit and the second securing unit comprises two studs.

8. The board assembly according to claim 7, wherein the supporting unit and the stubs are provided at opposite surfaces of the board.

9. The board assembly according to claim 6, wherein the board has holes for the supporting unit to pass through.

10. The board assembly according to claim 1, wherein each of the first securing unit and the second securing unit comprises two studs.

11. The board assembly according to claim 10, wherein the connector and the stubs are provided at opposite surfaces of the board.

12. The board assembly according to claim 1, wherein the locking elements are screws.

13. The board assembly according to claim 1, wherein the expansion card including a wireless network card or a television card.
